(19) United States
(12) Patent Application Publication
(10) Pub. No.: US 2025/0364798 A1
(43) Pub. Date: Nov. 27, 2025

(54) Pulse Width Modulated Fault Managed Power Systems

(71) Applicant: Schneider Electric USA, Inc., Andover, MA (US)

(72) Inventor: John J. Shea, Wake Forest, NC (US)

(73) Assignee: Schneider Electric USA, Inc., Andover, MA (US)

(21) Appl. No.: 18/872,728

(22) PCT Filed: Jun. 16, 2023
(86) PCT No.: PCT/US2023/025551

§ 371 Date: Dec. 6, 2024

Related U.S. Application Data
(60) Provisional application No. 63/352,825, filed on Jun. 16, 2022.

(51) Int. Cl. H02H 1/00; H02H 3/02; H02H 3/16; H02H 7/22

(52) U.S. Cl. CPC H02H 1/0007; H02H 3/023; H02H 3/025; H02H 3/167; H02H 7/226

(57) ABSTRACT

A fault managed power system (FMPS) and method therefor can limit the cumulative effects of repeated current pulses on the human body during a fault without changing the amplitudes of the current pulses. Upon detection of a fault, the fault managed power system progressively reduces the durations of the current pulses (i.e., ON intervals) instead of the amplitudes to limit the cumulative effects of the current pulses. The fault managed power system can perform the progressive pulse width reductions in increments or steps that limit the cumulative effects of the current pulses to below a predefined energy level. In some embodiments, the predefined level is a level that could prevent let-go or cause ventricular fibrillation in a human body. Such a fault managed power system advantageously provides a simple and efficient way to limit the energy delivered into a fault without having to change the amplitudes of the current pulses.

### CROSS-REFERENCE TO RELATED APPLICATIONS

This application for patent claims the benefit of priority to and incorporates herein by reference U.S. Provisional Application No. 63/352,825, entitled “Pulse Width Modulated Fault Managed Power System,” filed Jun. 16, 2022.

### TECHNICAL FIELD

Embodiments disclosed herein relate generally to fault protection in electrical power supplies and, more particularly, to methods and systems for supplying power that limit the energy delivered into a fault, and which can be combined with Ethernet or other communication protocols using either hardwire or fiber-optic cables, and the like.

### BACKGROUND

Supplying power over Ethernet is known as Power over Ethernet (PoE) and generally refers to the use of a conductor pair, typically a twisted-pair, to simultaneously send both electrical power and data. Thus, devices that can be powered via PoE, called powered devices (PD), generally do not require a separate power adapter to power the devices. Examples of powered devices include VoIP phones, HD video cameras (pan-zoom-tilt cameras), wireless access points (WAP), network routers, among other devices. The number of powered devices is expected to increase exponentially as demand for so-called “smart building” services grow.

Powered fiber cable (PFC) systems are similar to PoE systems insofar as electrical power and data are supplied over a single cable, thereby eliminating (or at least diminishing) the need for a separate power adapter to power the devices. With PFC, the data is sent over an optical fiber while the power is typically supplied over a conductive sheath, usually copper, that surrounds the optical fiber. A typical PFC cable can send data over a much greater distance compared to a typical PoE cable due to the lossless or nearly lossless characteristic of optical fibers.

In applications like PoE and PFC, power is typically injected onto the cable at between 44 and 57 Vdc, typically 48 Vdc, and transferred along the cable as a series of pulses. The voltage level allows the power to be efficiently transferred along the cable while still being low enough to be safe for end-users. The maximum power level allowed by the original industry standard for PoE power sourcing equipment (PSE) is 30 W. The new PoE standard, or PoE++ (IEEE 802.3bt), allows power levels up to 100 W. Standards that contemplate even higher power levels are being developed.

As power levels continue to increase in applications like PoE and PFC, a need exists for a way to ensure that the amount of energy delivered into a fault is limited.

### SUMMARY

Embodiments disclosed herein relate to methods and systems for supplying power that limit the energy delivered into a fault. The methods and systems provide a fault managed power system (FMPS) that can limit the cumulative effects of repeated current pulses on the human body during a fault without changing the amplitudes of the current pulses over time. Upon detection of a fault, the fault managed power system progressively reduces the durations or widths of the current pulses instead of their amplitudes to limit the cumulative effects of the current pulses. The fault managed power system can perform the progressive pulse width reductions in increments or steps that, when added all together, limit the cumulative effects of the current pulses over time to below a predefined level. In some embodiments, the predefined level is below a level that can prevent let-go or cause ventricular fibrillation in a human.

In some embodiments, the fault managed power system can perform the progressive pulse width reductions based on a predefined number of consecutive current pulses, or based on a predefined maximum allowed fault interval. In some embodiments, the fault managed power system can also limit performance of the progressive pulse width reduction sequence to a predefined number of attempts or iterations. after which the system is shut off or otherwise disabled if the fault still has not cleared. Such a fault managed power system advantageously provides a simple and efficient way to limit the energy delivered into a fault without having to change the amplitudes of the current pulses.

In general, in one aspect, the disclosed embodiments are directed to a fault managed power system. The system comprises, among other things, a source switch connected to receive a source voltage from a power source, the source switch further connected to an electrical cable and controllable to connect the power source to the electrical cable. The system also comprises an impedance sensor circuit connected to the electrical cable, the impedance sensor circuit configured to sense an impedance on the electrical cable. The system further comprises a controller coupled to the source switch and the impedance sensor circuit, the controller configured to receive the impedance sensed by the impedance sensor circuit and detect a presence of a fault on the electrical cable based on the impedance. The source voltage appears as current pulses on the electrical cable, each current pulse having an amplitude and a duration, and the controller is configured to perform pulse duration reduction on a predefined number of current pulses to limit a cumulative effect of the predefined number of current pulses to below a predefined threshold level, without reducing the amplitude of the predefined number of current pulses.

In general, in another aspect, the disclosed embodiments are directed to a method of managing fault in a power system. The method comprises, among other things, connecting a power source and an electrical cable using a source switch, the source switch configured to receive a source voltage from the power source and controllable to connect the power source to the electrical cable, the source voltage appearing as current pulses on the electrical cable when the power source is connected to the electrical cable, each current pulse having an amplitude and a duration. The method also comprises sensing an impedance on the electrical cable using an impedance sensor circuit connected to the electrical cable, and detecting a presence of a fault on the electrical cable based on the impedance of the electrical cable using a controller coupled to the impedance sensor circuit and the source switch. The method further comprises performing pulse duration reduction on a predefined number of current pulses using the controller to limit a cumulative effect of the predefined number of current pulses to below a predefined threshold level, without reducing the amplitude of the predefined number of current pulses.

In general, in yet another aspect, the disclosed embodiments are directed to a network. The network comprises, among other things, at least one network cable and a fault managed power system connected to the at least one network cable, the fault managed power system operable to provide a series of current pulses on the at least one network cable, each current pulse having an amplitude and a duration. The network further comprises at least one load connected to the at least one network cable and the fault managed power system, the at least one load being powered by the series of current pulses from the fault managed power system. The fault managed power system is further operable to detect a presence of a fault on the at least one network cable and perform pulse duration reduction on a predefined number of current pulses to limit a cumulative effect of the predefined number of current pulses to below a predefined threshold level, without reducing the amplitude of the predefined number of current pulses.

### BRIEF DESCRIPTION OF THE DRAWINGS

The foregoing and other advantages of the disclosed embodiments will become apparent upon reading the following detailed description and upon reference to the drawings, wherein:

FIG. 1A illustrates a series of current pulses having reduced amplitudes in a fault managed power system;

FIG. 1B illustrates a series of current pulses having the same amplitudes but progressively reduced pulse durations in a fault managed power system in accordance with an embodiment of the present disclosure;

FIG. 2 illustrates progressively reduced pulse durations with respect to a fault current limit curve in a fault managed power system in accordance with an embodiment of the present disclosure;

FIG. 3A illustrates a high-level view of an exemplary fault managed power system in accordance with an embodiment of the present disclosure;

FIG. 3B illustrates a more detailed view of an exemplary fault managed power system in accordance with an embodiment of the present disclosure;

FIG. 4 illustrates a method of performing progressively reduced pulse durations in a fault managed power system in accordance with an embodiment of the present disclosure:

FIG. 5A illustrates an example of a graph showing the voltage, as sensed, across a conductor(s), such as a power cable, over time, in relation to human body model in accordance with an embodiment of the present disclosure;

FIG. 5B illustrates an example of a graph showing the voltage, as sensed, across a conductor(s), such as a power cable, over time, in relation to human body model in accordance with an embodiment of the present disclosure;

FIG. 6 illustrates an example of a point-to-point architecture in which the fault managed power system can be employed, in accordance with an embodiment of the present disclosure;

FIG. 7 illustrates an example of a radial architecture in which the fault managed power system can be employed, in accordance with an embodiment of the present disclosure;

FIG. 8 illustrates an example of a daisy chain architecture in which the fault managed power system can be employed, in accordance with an embodiment of the present disclosure;

FIG. 9 illustrates an example of a fishbone architecture in which the fault managed power system can be employed, in accordance with an embodiment of the present disclosure:

FIG. 10 illustrates an enlarged partial view of the fishbone architecture of FIG. 9 with junction boxes, and loads and associated load-side component(s) in which the fault managed power system can be employed, in accordance with an embodiment of the present disclosure:

FIG. 11 illustrates a fault managed power system for a unipolar power configuration with a grounded source, 2-wire cable (shielded) and single switch, in accordance with an embodiment of the present disclosure;

FIG. 12 illustrates a fault managed power system for a unipolar power configuration with an isolated source, 2-wire cable (shielded) and single switch, in accordance with an embodiment of the present disclosure;

FIG. 13 illustrates a fault managed power system for a unipolar power configuration with an isolated source (no shield), 2-wire cable and single switch, in accordance with an embodiment of the present disclosure;

FIG. 14 illustrates a fault managed power system for a unipolar power configuration with a grounded source, 2-wire cable (shielded) and dual switch, in accordance with an embodiment of the present disclosure;

FIG. 15 illustrates a fault managed power system for a unipolar power configuration with an isolated source, 2-wire cable (shielded) and dual switch, in accordance with an embodiment of the present disclosure;

FIG. 16 illustrates a fault managed power system for a unipolar power configuration with an isolated source (no shield), 2-wire cable and dual switch, in accordance with an embodiment of the present disclosure;

FIG. 17 illustrates a fault managed power system for a bipolar power configuration with a grounded source, 3-wire cable (shielded) and dual switch, in accordance with an embodiment of the present disclosure;

FIG. 18 illustrates a fault managed power system for a bipolar power configuration with an isolated source, 3-wire cable (shielded) and dual switch, in accordance with an embodiment of the present disclosure;

FIG. 19 illustrates a fault managed power system for a bipolar power configuration with an isolated source (no shield), 3-wire cable and dual switch, in accordance with an embodiment of the present disclosure; and

FIG. 20 illustrates an example of sample data of a calibration table such as voltage reference (Vref) Table, in accordance with an embodiment of the present disclosure.

### DETAILED DESCRIPTION OF THE DISCLOSED EMBODIMENTS

As an initial matter, it will be appreciated that the development of an actual, real commercial application incorporating aspects of the disclosed embodiments will require many implementation specific decisions to achieve the developer's ultimate goal for the commercial embodiment. Such implementation specific decisions may include, and likely are not limited to, compliance with system related, business related, government related and other constraints, which may vary by specific implementation, location and from time to time. While a developer's efforts might be complex and time consuming in an absolute sense, such efforts would nevertheless be a routine undertaking for those of skill in this art having the benefit of this disclosure.

It should also be understood that the embodiments disclosed and taught herein are susceptible to numerous and various modifications and alternative forms. Thus, the use of a singular term, such as, but not limited to, “a” and the like, is not intended as limiting of the number of items. Similarly, any relational terms, such as, but not limited to, “top,” “bottom,” “left,” “right,” “upper,” “lower,” “down,” “up,” “side,” and the like, used in the written description are for clarity in specific reference to the drawings and are not intended to limit the scope of the invention.

As mentioned above, power levels continue to increase in applications like PoE, PFC and other applications that supply power to powered devices. For example, industry standard ANSI/NFPA 70 was recently released by the National Electrical Code (NEC) that defines a new Class 4 power system. These Class 4 power systems have voltage ratings of up to 450 V with no power limits while retaining the safety of PoE systems and lower class systems. To qualify as Class 4, power systems must be able to satisfy certain safety requirements regarding the energy delivered into a fault. In particular, Underwriters Laboratories standard UL-1400-1 requires that in the event of a fault, the amplitude of repetitive current pulses must be reduced to limit the cumulative effects of the current pulses over time to below a “let-go” limit (i.e., a voltage and current level that can prevent let-go as defined by UL-1400-1). Table 1 below lists the reductions in amplitude for repetitive current pulses as a percentage or ratio (see UL-1400-1, Table 5.5).

TABLE 1
Current Reduction for Repetitive Pulses

| n | Cₜ(n) |
|---|---|
| 1 | 1.00 |
| 2 | 0.65 |
| 3 | 0.42 |
| 4 | 0.27 |
| 5 | 0.18 |
| 6 | 0.12 |
| 7 | 0.10 |

In Table 1, a current reduction multiplier, Cₜ(n), specifies the percentage reductions in amplitude for the first seven current pulses after detection of a fault. As can be seen, the current reduction multiplier Cₜ(n) begins at 1.00 (100%) and progressively decreases to 0.10 (10%). This means that the amplitude of the first current pulse after detection of a fault (n=1) is multiplied by 1.00 (no reduction), while the amplitude of the second current pulse (n=2) is multiplied by 0.65 (reduced to 65% of its original level), the amplitude of the third current pulse (n=3) is multiplied by 0.42 (reduced to 42% of its original level), and so forth as shown in the table. After seven pulses, a 3-second timeout interval is imposed during which all further current pulses are stopped, and a determination is made whether the fault has cleared. If it is determined that the fault has not cleared, then the above amplitude reduction sequence is repeated for an additional seven current pulses. If the fault still has not cleared after a predetermined number of attempts of the amplitude reduction sequence, then the system is shut off or otherwise disabled.

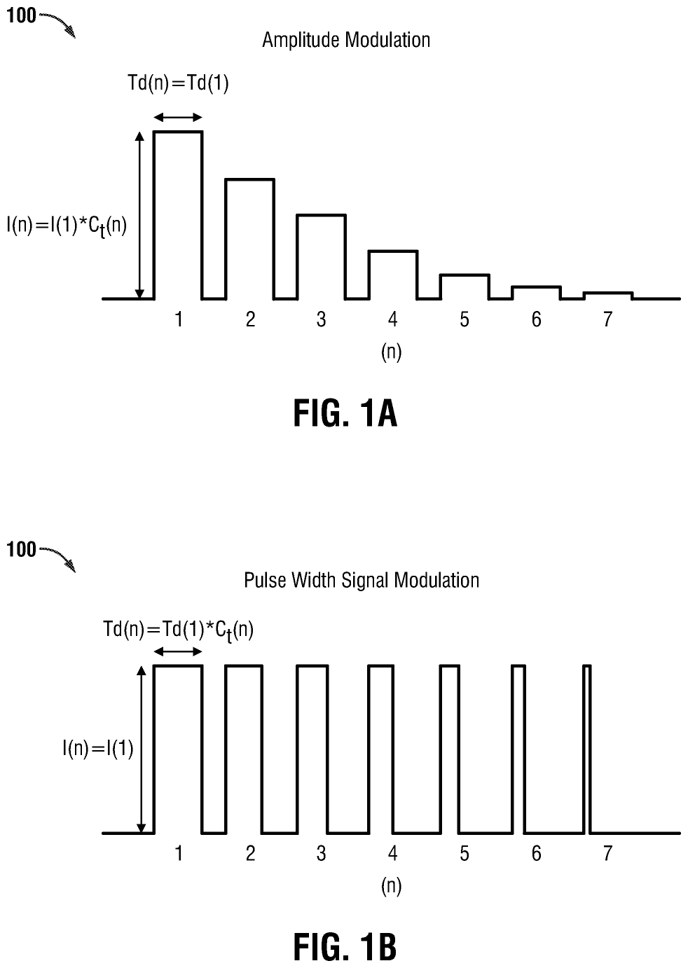

FIG. 1A illustrates the above amplitude reduction sequence for a series of seven current pulses 100 of the type commonly found in power systems that supply power to powered devices. As the figure shows, each of the current pulses in the series of current pulses 100 has the same pulse width or duration as the first current pulse, Td(n)=Td(1). This pulse duration is simply the nominal/standard pulse duration being used in the power system to supply power to powered devices. The amplitudes of the current pulses, however, are not all the same. Each current pulse has an amplitude that has been multiplied by the current reduction multiplier, I(n)=I(1)*Cₜ(n), as specified by UL-1400-1. This results in the cumulative effects of the series of current pulses 100 over time being limited to a predefined energy level, which for purposes of UL-1400-1 means below a level that could prevent let-go or cause ventricular fibrillation in a human.

FIG. 1B illustrates an alternative scheme for limiting the cumulative effects of the series of current pulses 100 over time that may be used by a fault managed power system as disclosed herein. In FIG. 1B, instead of reducing the amplitude of the current pulses upon detection of a fault, the fault managed power system herein uses the current reduction multiplier Cₜ(n) specified in Table 1 to progressively reduce the duration of the current pulses, Td(n)=Td(1)*Cₜ(n). This allows the fault managed power system to achieve the same result of limiting the cumulative effects of the series of current pulses 100 over time, but without reducing the amplitudes of the current pulses (I(n)=I(1)).

It should be understood that while the pulse width reduction scheme depicted in FIG. 1B has the advantage of satisfying the requirements of UL-1400-1, the fault managed power system herein is not so limited. Those having ordinary skill in the art will understand that variations and modifications are available based on the requirements of the particular system or application, within the scope of the present disclosure. For example, instead of seven current pulses, fewer than seven current pulses (e.g., six, five, etc.), or more than seven current pulses (e.g., eight, nine, etc.) may be used by appropriate adjustment of the current reduction multiplier Cₜ(n). Similarly, instead of a different current reduction multiplier value being applied to each current pulse, the same current reduction multiplier value may be applied to two or more consecutive current pulses by using an appropriately modified Cₜ(n). Indeed, the fault managed power system herein may apply the same current reduction multiplier value (i.e., a constant value) to all current pulses in the series of current pulses 100 by using an appropriately selected multiplier (e.g., 50%). Moreover, instead of specific multiplier values, the progressive decrease in the current reduction multiplier Cₜ(n) may be achieved using an appropriate equation (e.g., via curve fitting or similar techniques).

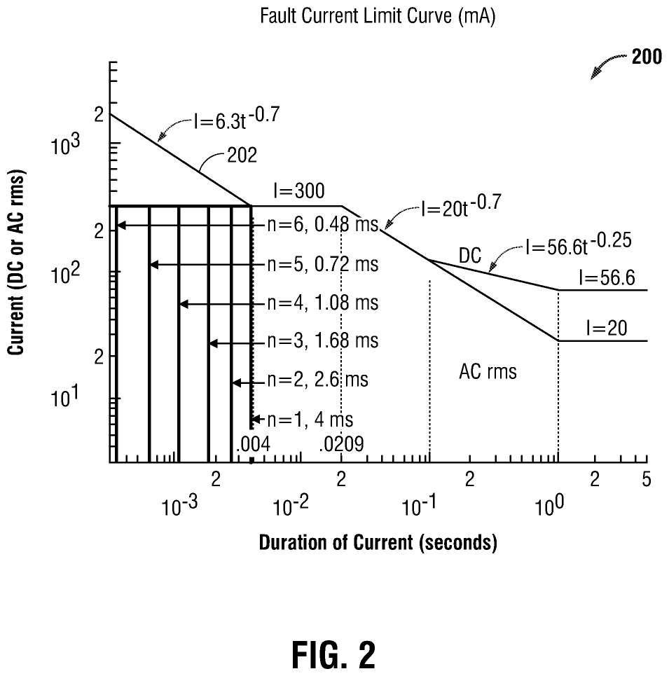

FIG. 2 shows a graph 200 illustrating how the pulse width reduction scheme of the fault managed power system herein can be used to limit the cumulative effects of repetitive current pulses, as required by UL-1400-1. In the graph 200, the vertical axis represents current (DC or AC rms) in milliamps (mA) and the horizontal axis represents current duration in seconds. Both axes are shown in a logarithmic scale (i.e., a log-log graph). Line 202 shows the fault current limits specified by UL-1400-1 in order to limit the cumulative effects of repetitive current pulses to below a level that can prevent let-go or cause ventricular fibrillation in a human. There are two current curves represented by line 202, one curve for DC and one for AC, that overlap completely for fault event durations lasting less than 100 ms, but diverge for longer fault event durations.

In the example of FIG. 2, the fault managed power system is providing power in the form of current pulses that have a nominal or standard pulse duration of 0.004 seconds (Td=4 ms) and a nominal or standard amplitude of 300 mA (I=300 mA). The line denoted as n=1 represents the first current pulse after detection of a fault, while the line denoted as n=2 represents the second current pulse, and so on. As can be seen, the fault managed power system herein has progressively reduced the duration or width of the second current pulse to 2.6 ms, the third current pulse to 1.68 ms, the fourth current pulses to 1.08 ms, and so on, using the current reduction multiplier Cₜ(n) set forth in Table 1. This progressive pulse width reduction results in the cumulative effects of the repetitive current pulses being limited to the level defined by line 202, thus providing an equivalent current-time exposure as that given in the requirements of UL-1400-1. Note that the seventh current pulse, although present, is not expressly shown here due to the size limitations of the figure.

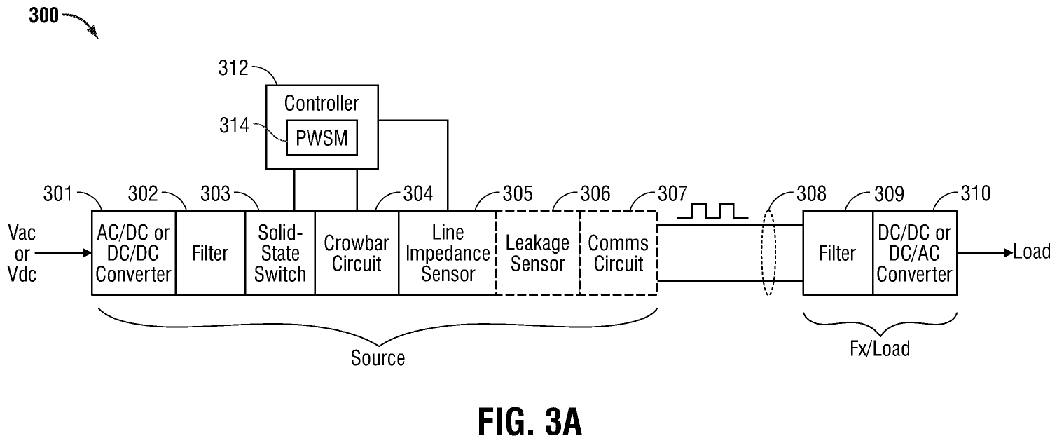

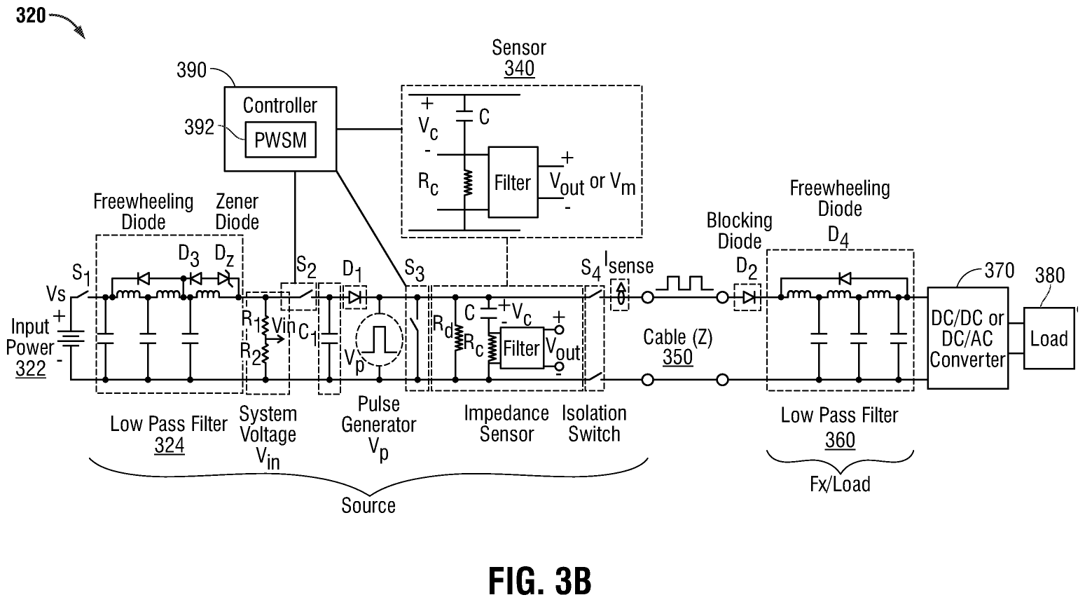

Referring now to FIG. 3A, a high-level diagram is shown for an exemplary fault managed power system 300 that can perform the progressive pulse width reduction discussed above upon detection of a fault. The power system 300 in this example is composed mainly of upstream components, or source-side components (“source”). For example, there is an AC/DC or DC/DC converter 301 configured to receive electrical power from an AC or DC power source, a filter 302, such as a pi-filter, configured to provide noise filtering of the electrical power, and a switch 303, such as a solid-state switch, configured to connect/disconnect the electrical power. The power system 300 further includes a crowbar circuit 304 configured to selectively implement a short-circuit across the output of the power system 300, and a line impedance sensor 305 configured to output a line impedance, which can then be used to detect leakage current indicative of a fault. Optionally, a leakage sensor 306 may be provided to directly detect leakage current indicative of the fault. A communications circuit 307, also optional, may be provided to implement power line communication (PLC) via the power system 300.

An electrical power cable 308 is connected between the source-side components discussed above and one or more downstream or load-side components (“Fx”). The electrical power cable 308 is configured to deliver DC current/voltage (e.g., DC steady state current) from the source to the load-side components. The load-side components in this embodiment include a filter 309 similar to the source-side filter 302, whereby the two filters 302, 309 are configured to isolate the power cable 308 from the source-side power supply and the load-side loads, thereby providing noise-free DC current/voltage across the cable to a DC/DC or DC/AC converter 310 that converts the power into a form that can be used by the load.

A controller 312 is provided to implement the various functions and operations as described herein, including but not limited to, control of the operation of one or components of the power system 300, to perform or implement fault detection, and to manage a supply of electrical power/energy from the power source to or across the cable 308. To this end, the controller 312 is equipped with or programmed to execute, among other things, a pulse width signal modulation module (PWSM) 314 configured to perform the progressive pulse width reduction sequence described herein. Any suitable programmable controller or microcontroller may be used to implement the controller 312 and the pulse width signal modulation module 314, including, for example, part number STM32L476RG, a programmable microcontroller with integrated A/D converter and embedded and external storage/memory, available from ST Microelectronics.

FIG. 3B illustrates an exemplary fault managed power system 320 that has been implemented consistent with the high-level diagram shown in FIG. 3A. The power system 320 in this figure mainly includes a power supply 322, a switch S1, an upstream filter 324 such as a low-pass filter, resistors R1 and R2, a switch S2, a capacitor C1, a diode D1, a switch S3, a line impedance sensor 340, an isolation switch S4, a current sensor for sensing a current (e.g., Isense), a power cable 350, a blocking diode D2, a downstream filter 360, such as a low-pass filter, a power converter 370, such as a DC/DC or DC/AC converter, and one or more loads 380. The power system 320 also can include one or more controllers 390, at least one of which is equipped with or programmed to execute a pulse width signal modulation (PWSM) module 392 therein, for controlling the various components of the system 320, and controlling, implementing or causing the various operations and functions described herein. As alluded to above, the upstream components between the power supply 322 and the cable 350 can generally be referred to as source-side components, while the components downstream of the cable 350 or between the cable 350 and the load 380 can generally be referred to as downstream or load-side components or (“Fx”).

The power supply (or power source) or input power 322 can be an AC or DC power supply. When an AC power supply is employed, the power system 320 can further include a power converter such as an AC/DC converter so that DC electrical power is supplied across the cable 350. In various embodiments, when a DC power supply is employed, the power system 320 can further include a power converter such as a DC/DC converter. The power supply/input power 322 can provide a system voltage Vs.

The switch S1 is a switch that is operable to connect or disconnect the power supply 322 to or from components, which are downstream from the source, including the cable 350. The switch S1 can be a mechanical switch or other switch, which can be operated to an open position to disconnect the power supply 322 from such components and to a closed position to connect the power supply to such components. The switch S1 can be operated manually or automatically. In other embodiments, the switch S1 can instead be located in the line side (source side) of the AC/DC power source.

The upstream filter 324 and downstream filter 360 can be a low-pass filter, such as a pi-filter (also referred to as π-filter), which may employ LC components (or circuits). The filters 320, 360 can be configured to isolate the cable 350 from source-side/upstream noise and load-side/downstream noise to enable noise-free delivery of DC current/voltage across the cable 350. In this example, the upstream filter 324 can also include one or more freewheeling diodes D3 and Zener diodes Dz, and the downstream filter 360 can include one or more freewheeling diodes D4.

The resistors R1 and R2 can be configured to provide a voltage Vin, which can be a scaled system voltage corresponding to an applied (operating) system voltage for the source circuit. In this example, the voltage Vin can equal Vₛ*(R2/(R1+R2)) or the voltage V_{S} can equal Vin*((R1+R2)/R2).

The switch S2 can be an electronic switch, which can be operated to rapidly disconnect the supply of power provided by the power supply 322 from the cable 350, and to connect the supply of power provided by the power supply 322 to the cable 350. In this example, the switch S2 can be a solid-state switch.

In various embodiments, a pulse generator (or generating circuitry) can be provided or implemented on or by the source through operation of the switch S2, which can be controlled to generate an electrical pulse(s), such as for example, by turning ON the switch S2 for a short period (e.g., ˜500 us), then turning OFF the switch. The pulse generator can be configured to generate an electrical pulse, such as for example a voltage Vp (or current) which can be supplied to the cable 350. In various embodiments, electrical pulses, such as voltage pulses, can be generated to have a pulse frequency within the frequency range which is filtered-out by the filters 320, 360. For example, the frequency can be a high frequency, and the magnitude of the voltage can be sufficiently small (e.g., within a touch-safe range). Furthermore, in some embodiments, the switch S2 can be controlled to generate an electrical pulse(s), such as for example, by turning ON the switch S2 for a short period (e.g., ˜500 us), then turning OFF the switch. Although a pulse generator or circuit thereof can be implemented through operation of the switch S2, it should be understood that other pulse generating circuitry may be incorporated into the source to produce an electrical pulse(s) as desired, in accordance with an embodiment.

The switch S3 can be an electronic switch, which can be operated to short-circuit the source or source-side components, to rapidly interrupt and prevent the supply of power from the power supply 322 to the cable 350. In this example, the switch S3 can be a crowbar circuit, which rapidly short-circuits, or in other words crowbars, the supply line, for example, if the voltage and/or current exceeds predefined thresholds (i.e., in the event of a fault).

The line impedance sensor 340 can sense or measure electrical energy on the cable 350. The sensor 340 can include an impedance sensor and a frequency selective filter, such as a pi-filter. In various embodiments, the impedance sensor in combination with the pi-filter can provide for a tank circuit (also referred to herein as “impedance sensor tank circuit”), which can output an amplified voltage measurement (Vm or Vout), which can correspond to an impedance difference on the cable 350 or leakage current on the cable 350. The sensor measurement can be used to detect an occurrence or presence of a fault or fault signal associated therewith (e.g., human body touch or other faults on the cable 350). In this example, the impedance sensor 340 can include a resistor R_{c} and an RC circuit (or component), and the filter can be a pi-filter which can include an LC circuit (or component). In this example, the capacitor in the impedance sensor of the sensor 340 and the inductor in the pi-filter can form a tank circuit for tuning desired frequencies or ranges in order to measure and detect for electrical disturbances such as, for example, those due to fault signal(s) across the cable 350. In an embodiment, the impedance sensor can work in combination with the pi-filter components, such as primarily the inductor and capacitor closest to the impedance sensor, to provide for the tank circuit.

In various embodiments, the tank circuit can be configured to measure frequency signals in the pulse frequency range of the generated electrical pulses to facilitate detection of electrical disturbances on the power cable.

The switch S4 can be an isolation switch, which can be operated to connect or disconnect the source to or from component(s) (also referred to as circuit(s)) that are downstream from the source. In various embodiments, the switch S4 can be operated to isolate the source circuit from component(s) that are downstream, such as the power cable 350, load(s) and load-side component(s) such as downstream filter and so forth. The source circuit can be isolated, for example, when performing an open circuit test (e.g., testing in an open circuit state) when measuring reference voltages for calibration purposes, such as described herein.

The current sensor can be used to sense a current (e.g., Isense) on the cable. The current sensor can be used to detect leakage current or other current signal(s), including fault signal(s), on the cable.

The power cable 350 can be an electrical cable, which can include one or more conductors (e.g., conductors, conductive lines, conductive wires, etc.). In various embodiments, the cable can be 2-wire (twisted) cable, 3-wire (twisted) cable, and so forth. The cable also can be shielded, or unshielded.

The converter 370 can be a power converter such as DC/DC converter or a DC/AC converter. The type of converter can depend on various factors, including the application, load and so forth.

The one or more controllers 390, and pulse width signal modulation (PWSM) module 392 thereof, can be configured to implement the various functions and operations as described herein, including but not limited to control of the operation of one or components of the power system 320, to perform or implement of fault detection, and to manage a supply of electrical power/energy from the source to or across the cable 350. The one or more controllers 390 can include an internal memory or be communicatively coupled to an external memory. The memory can store among other things, executable instructions or programs for controlling the operations of the controller (including functions and operations described herein), data for use in implementing fault managed power method and system including system variables (e.g., counter, operating parameters, reference tables such as voltage reference tables, etc.), and any other data described herein.

The above-described fault managed power system 320 of FIG. 3 is simply provided as an example. The fault managed power system can be modified, such as to employ one or more switches, upstream and/or downstream power converters, one or more sensors (e.g., impedance sensor(s), current leakage sensor(s) or other sensors to detect fault due to human contact with the cable or other types of faults on the power system), different types of cables and architectures, and so forth. The fault managed power system also can include communication devices, which may be incorporated upstream and downstream of the power cable to implement power line communication (PLC) across the fault managed power system, or a power distribution system including the fault managed power system.

For example, in an embodiment, the fault managed power system 320, via the one or more controllers 390 thereof, can be configured to detect an electrical disturbance on the power cable 350 corresponding to occurrence of a fault resulting from human body contact with the cable 350 (or its conductive line) or other fault on the cable 350, based on measurements from the sensor 340, when the electrical pulses or the DC current/voltage and electrical pulses are supplied to the power cable 350, and in response to detection of such a fault, perform the progressive pulse width reduction sequence described above.

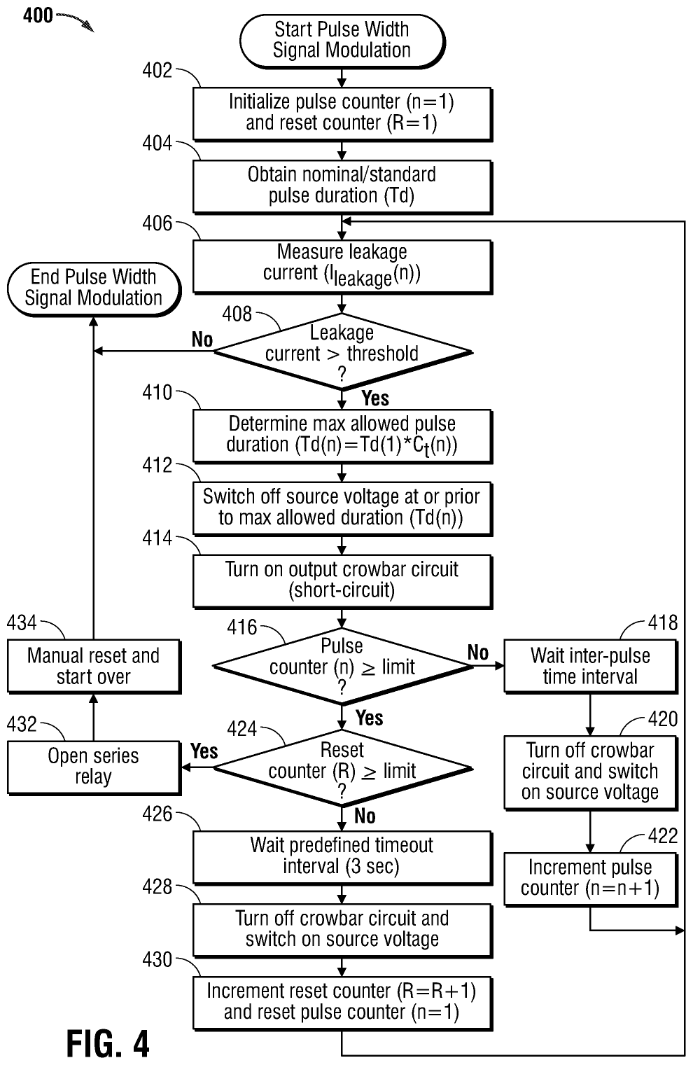

FIG. 4 is a flowchart representing a method 400 that may be used by or with embodiments of the fault managed power system herein to perform progressive pulse width reduction upon detection of a fault to limit the cumulative effects of the current pulses to below a predefined energy level. In particular, the method 400 may be executed by the one or more controllers of the disclosed fault managed power system, and the pulse width signal modulation module therein, in conjunction with one or more of the sensors and circuits of the fault managed power system.

The method 400 generally begins at block 402 where a pulse counter is initialized (n=1) and a reset counter is likewise initialized (R=1). The pulse counter (n) is used to track the number of consecutive current pulses that appear on the power cable after detection of a fault, and the reset counter (R) is used to track how many consecutive attempts or iterations of progressive pulse width reductions have been performed. At block 404, a nominal/standard current pulse duration Td(1) is obtained, for example, from a predefined location in a storage/memory of the one or more controllers of the fault managed power system. Alternatively, where applicable, the nominal/standard current pulse duration (Td) may be determined on an as needed basis, for example, by measuring the time between the rising and falling edges of one or more current pulses in the system prior to starting the method 400, in a manner known to those skilled in the art.

At block 406, any leakage current that may be present on the cable is measured, for example, using an impedance sensor as described above or other techniques known to those skilled in the art. At block 408, a determination is made whether the leakage current exceeds a predefined threshold, indicating that a fault is present, such as due to contact with the human body. If the determination at block 408 is yes, indicating that a fault has been detected, then at block 410, a maximum allowed pulse duration is determined for the first current pulse (n=1) after detection of the fault. In some embodiments, determining the maximum allowed pulse duration is performed by applying the current reduction multiplier Cₜ(n) from Table 1 to the pulse duration, Td(n)=Td(1)*Cₜ(n).

At block 412, a source switch (e.g., a solid-state switch) is controlled to switch off the source voltage of the fault managed power system at or prior to (i.e., near to) expiration of the maximum allowed pulse duration from the previous block to quickly cut off the current pulse. At block 414, a crowbar (e.g., a crowbar circuit) is turned on to implement a short-circuit across the cable to quickly cut off the current pulse at or prior to (i.e., near to) expiration of the maximum allowed pulse duration.

At block 416, a determination is made whether the pulse counter has reached a predefined pulse counter limit. In some embodiments, the pulse counter limit may be seven current pulses (i.e., pulse counter limit=7), although a different limit may certainly be used depending on the requirements of the particular system or application. If the pulse counter has not reached the pulse counter limit, then at block 418, an inter-pulse time interval is waited to allow for the start of the next current pulse in the sequence of current pulses to arrive (or simulate the arrival of the next current pulse). At block 420, the crowbar is turned off to remove the short-circuit across the cable and the source switch is switched on to restore the source voltage to the system. At block 422, the pulse counter is incremented by one to track the number of pulses that have appeared on the cable since detection of the fault. Thereafter, a return to block 406 is made to measure any leakage current or otherwise detect that the fault may still be present on the cable.

On the other hand, if the pulse counter has reached the pulse counter limit at block 416, then a determination is made at block 424 whether the reset counter has reached a predefined reset counter limit. In some embodiments, the reset counter limit may be three attempts or iterations (reset counter limit=3), although a different limit may certainly be used depending on the requirements of the particular system or application. If the reset counter has not reached the reset counter limit, then at block 426, a timeout interval is waited to allow for fault to clear. In some embodiments, the timeout interval may be three seconds, although a different timeout interval may certainly be used. At block 428, the crowbar circuit is turned off and the source voltage is turned back on. At block 430, the reset counter is incremented by one, and the pulse counter is set back to its initial value. From there, the method returns again to block 406 to measure any leakage current or otherwise detect that the fault may still be present on the cable.

If the reset counter has reached the reset counter limit at block 424, then this indicates that the fault still has not cleared and potentially poses a serious problem, and therefore the system needs to be shut down or otherwise disabled for safety purposes. Thus, at block 432, a series relay (e.g., isolation switch S4) is opened to isolate the power source from the cable and downstream equipment. In addition to opening the series relay, the switch connecting the power system to the power source (i.e., switch S1) can also be opened to further isolate the power source. Thereafter, at block 434, manual reset of the system is performed, after which the system is restarted.

As noted above, the various embodiments of the fault managed power system disclosed herein operate on a series of current pulses (i.e., a pulse train), each current pulse having an amplitude and a duration. To this end, in some embodiments, the fault managed power system herein may be configured as a pulsed system that inherently supplies the source voltage as pulse train on the cable. In other embodiments, the fault managed power system herein may be configured as a type of system that produces a DC source voltage which is then modulated upon detection of a fault in the manner discussed with respect to method 400 of FIG. 4 (e.g., using a source switch (switch S2) and crowbar circuit (switch S3)) to create current pulses that have progressively reduced durations.

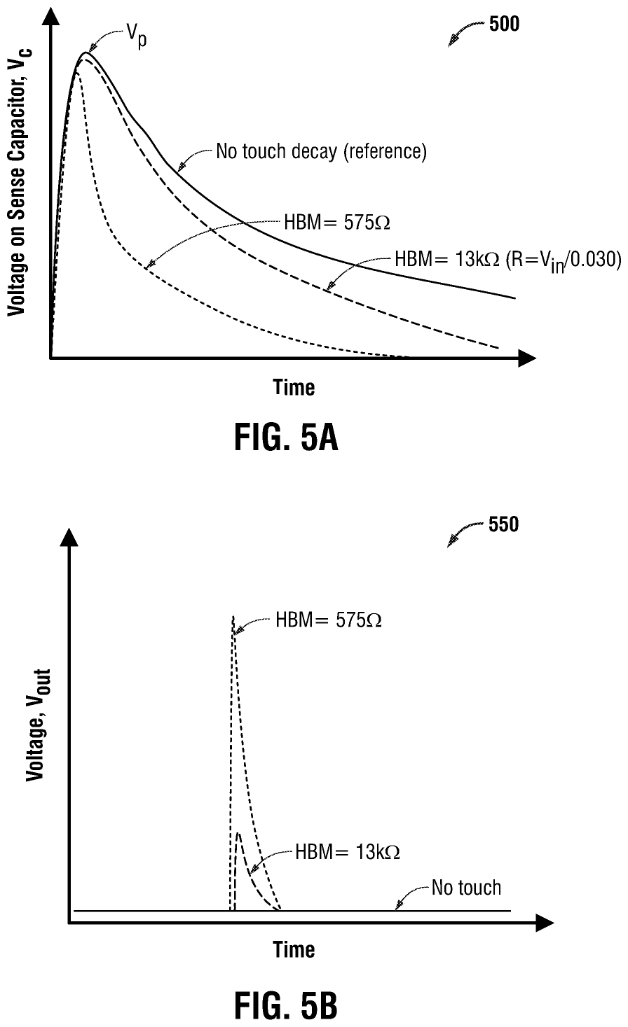

FIG. 5A illustrates an example of a graph 500 showing a voltage, as sensed, across a conductor(s), such as a power cable, over time, in relation to human body models (HBMs) in accordance with an embodiment of the present disclosure, for purposes of detecting leakage current due to a fault. In this example, the voltage Vc can be the voltage of a sense capacitor (e.g., the capacitor of the impedance sensor 140 of FIG. 1) in relation to a start-up stage. Similarly, FIG. 5B illustrates an example of a graph 550 showing the voltage, as sensed, across a conductor(s), such as a power cable, over time, in relation to human body models (HBMs) in accordance with an embodiment of the present disclosure. In this example, the voltage Vout can be the outputted voltage from a sensor (e.g., the impedance sensor tank circuit of FIG. 3B) in relation to a steady state operation stage.

On the graphs 500 of FIG. 5A and 550 of FIG. 5B, there is shown sensed voltage profiles of different human body models (e.g., different resistances) which can reflect different types of human body contact with the cable, e.g., body part in contact with the cable, amount of body contact to the cable, line-to-line human body contact, line-to-ground human body contact, and the like. HBMs can be predetermined for different human body contact scenarios, including no-touch/contact scenario. The HBMs can be used as a proxy for actual human testing to test the detection of a fault, such as human contact with the cable, based on measurements of electrical properties of the monitored cable. Other voltage models also may be employed to detect for other types of faults on a power cable, based on sensor measurements.

For example, a DC fault managed power system can employ filters at both source and load (or Fx) sides, such as described herein, which in turn can provide “noise free” DC voltage or current on an interconnecting electrical cable. The introduction of a fault (e.g., human body contact, etc.) can create a disturbance pulse that can be measured by a sensor. The sensor can output a voltage or other electrical measurement, which can correspond to a change of impedance on the monitored cable or to leakage current on the monitored cable. For instance, the peak of the pulse can be proportional to the leakage current. The presence of a pulse at Vc or Vout can indicate human body contact on one or more conductors of a cable connecting the source-side/upstream and load-side/downstream filters. The filters can be low-pass filters such as π-filters, or other low-pass filters for filtering out noise such as high frequency noise or signals. In response to detection of the occurrence of such a fault, the fault managed power system can interrupt or prevent supply of power (e.g., voltage, current, etc.) across the cable, using switches (or the like). In various embodiments, fast switching off and crowbarring can allow a fault managed power system to satisfy shock/fire requirements for a Class 4 power system and other safety requirements.

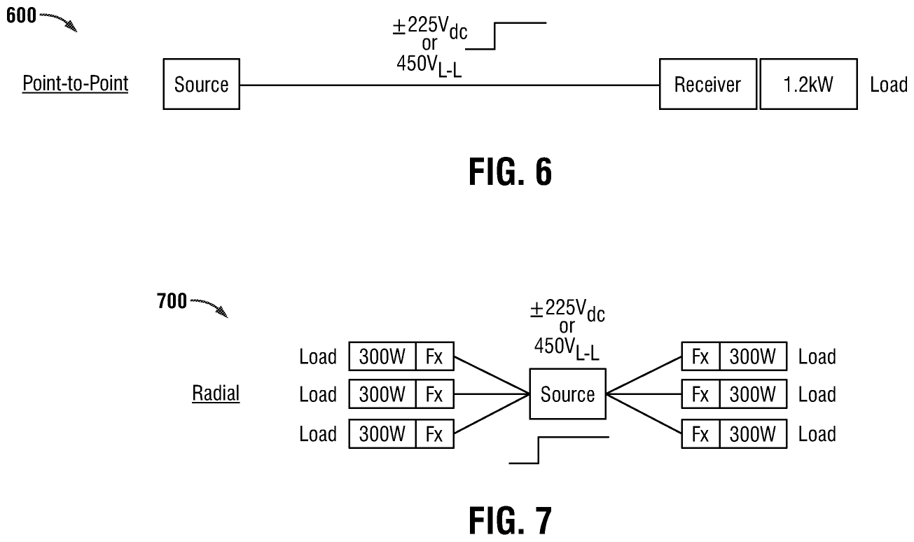

FIGS. 6 through 10 illustrate various power distribution architectures, which may employ the fault managed power method and system as described herein. In general, these various architectures include one or more sources, one or more downstream components (load-side components or Fxs), and one or more power cables connected between source(s) and load-side component(s). As described herein, the source and the downstream component(s) can include upstream and downstream filters to isolate the cable from noise (e.g., filter out any noise in desired frequency ranges from the upstream power supply and the downstream load(s)), and the source can include a pulse generation circuitry and impedance sensor to measure electrical activity on the power cable. The measurements from the sensor can be used, for example, by a controller(s), to detect an occurrence of a fault, such as human body contact with the cable or other fault. In response to detection of an occurrence of a fault, electrical energy supplied to one or more power cables is interrupted (or prevented) using one or more switches. These example architectures are described in further detail below.

FIG. 6 illustrates an example of a point-to-point architecture 600 in which the fault managed power system (as described herein) can be employed, in accordance with an embodiment of the present disclosure. As shown in FIG. 6, the architecture 600 includes a source, a downstream component(s), and a power cable connected between the source and the downstream component(s). The power cable can deliver electrical energy from a single source to a single group of downstream component(s) or Fx. The supplied electrical energy can be unipolar voltage (e.g., 450 Volts) or bipolar voltage (e.g., +225 Volts).

FIG. 7 illustrates an example of a radial architecture 700 in which the fault managed power system (as described herein) can be employed, in accordance with an embodiment of the present disclosure. As shown in FIG. 7, the architecture 700 includes a single source which can supply electrical energy to a plurality of groups of downstream component(s) or Fx (and their associated loads) over respective power cables. A fault managed power subsystem can be implemented between the source and each group of downstream component(s) or Fx. The supplied electrical energy can be unipolar voltage (e.g., 450 Volts) or bipolar voltage (e.g., ±225 Volts).

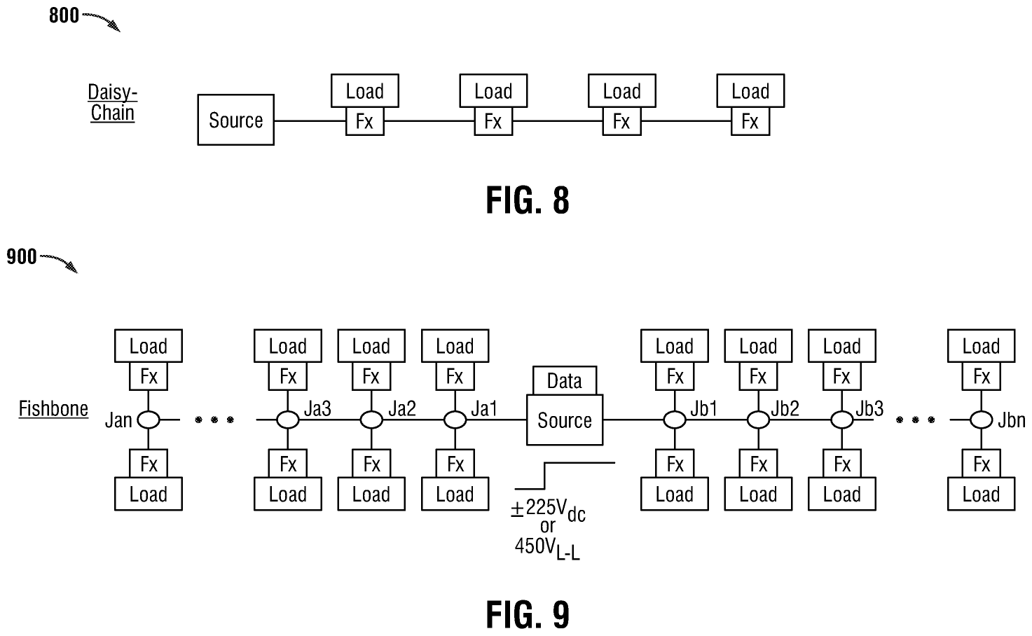

FIG. 8 illustrates an example of a daisy chain architecture 800 in which the fault managed power system (as described herein) can be employed, in accordance with an embodiment of the present disclosure. As shown in FIG. 8, the architecture 800 includes a single source which can supply electrical energy to a plurality of groups of downstream component(s) or Fx (and their associated loads). The groups of downstream component(s) or Fx are connected in series across power cables. The supplied electrical energy can be unipolar voltage (e.g., 450 Volts) or bipolar voltage (e.g., ±225 Volts).

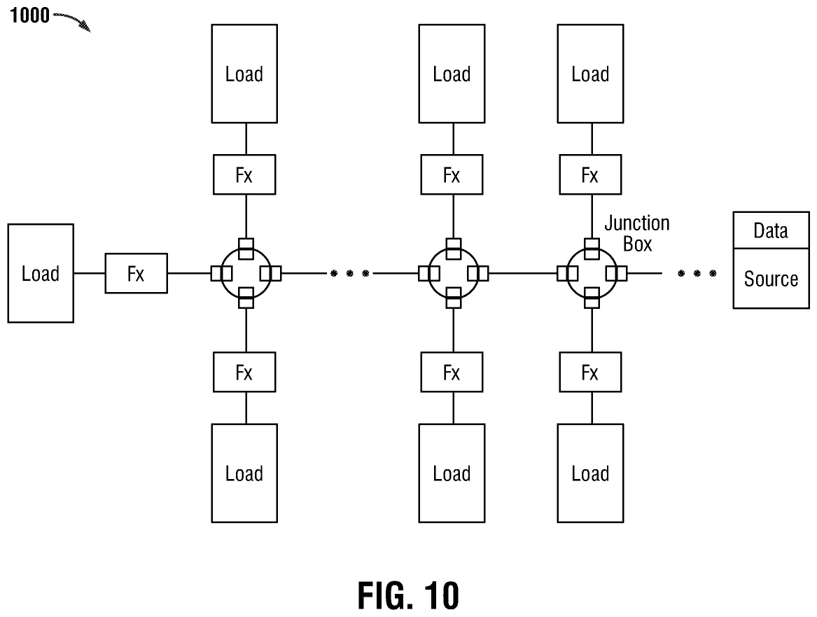

FIG. 9 illustrates an example of a fishbone architecture 900 in which the fault managed power system (as described herein) can be employed, in accordance with an embodiment of the present disclosure. As shown in FIG. 9, a source is connected to one or more series of junction boxes, which in turn are connected to a plurality of groups of downstream component(s) or Fx (e.g., a pair of groups of downstream component(s) or Fx). The supplied electrical energy can be unipolar voltage (e.g., 450 Volts) or bipolar voltage (e.g., ±225 Volts). Power line communication can be conducted to transmit data across the fishbone architecture, for example by using frequencies which are not filtered out by the upstream or downstream filters or in the frequency ranges for detecting a fault. An enlarged partial view of the fishbone architecture of FIG. 9 is shown in the architecture 1000 of FIG. 10.

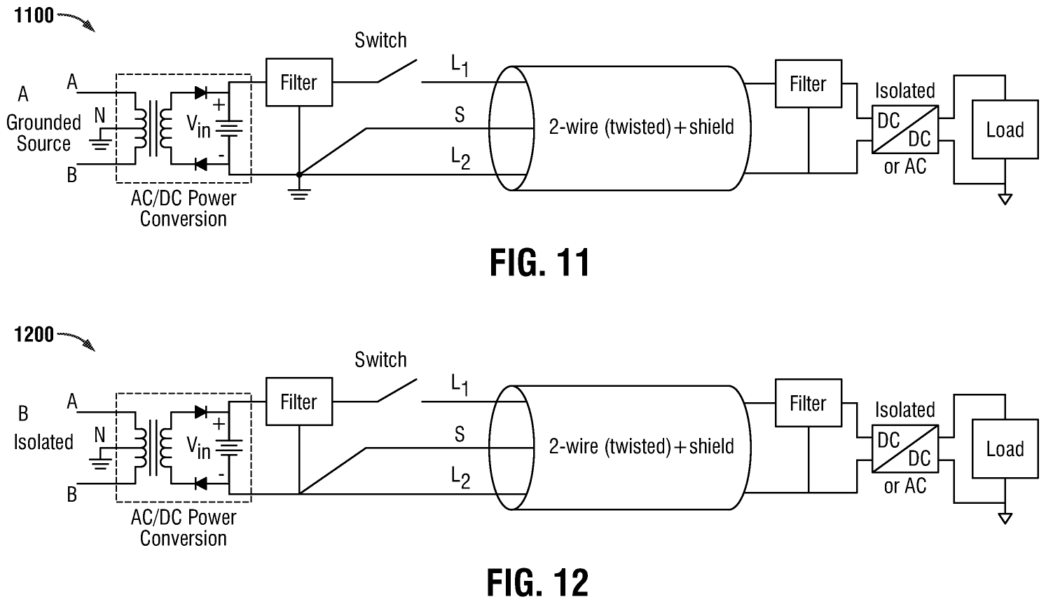

FIGS. 11 through 19 illustrate various examples of cable configuration, which can be employed in a fault managed power method and system (as described herein). In addition to the upstream and downstream filters, switch(es), power cable and power converter(s), the fault managed power system in these examples also can include additional upstream components, which may be incorporated on the source-side. These components can include a pulse generation circuitry and impedance sensor to measure electrical activity on the power cable. The measurements from the sensor can be used, for example, by a controller(s), to detect an occurrence of a fault, such as human body contact with the cable or other fault. In response to detection of an occurrence of a fault, electrical energy supplied to one or more power cables is interrupted (or prevented) using one or more switches. These exemplary fault managed power system are described in further detail below.

FIG. 11 illustrates a fault managed power system 1100 which employs a unipolar power configuration, in accordance with an embodiment. As shown in FIG. 11, the power system 1100 can include: a source including an upstream grounded source, an upstream power converter (e.g., AC/DC converter), an upstream filter and a single switch; a power cable; and a downstream component(s) including a downstream filter and downstream power converter (e.g., DC/DC converter or DC/AC converter) which is connected to a load. In this example, the power cable is a 2-wire (twisted) cable, which is shielded. As shown, the power cable includes conductors, such as line L1 and L2, and a shield s. The upstream switch is connected between the upstream filter and the conductor L1.

FIG. 12 illustrates a fault managed power system 1200 which employs a unipolar power configuration, in accordance with an embodiment. As shown in FIG. 12, the power system 1200 can include: a source including an upstream isolated source, an upstream power converter (e.g., AC/DC converter), an upstream filter and a single switch; a power cable; and a downstream component(s) including a downstream filter and downstream power converter (e.g., DC/DC converter or DC/AC converter) which is connected to a load. In this example, the power cable is a 2-wire (twisted) cable, which is shielded. As shown, the power cable includes conductors, such as line L1 and L2, and a shield s. The upstream switch is connected between the upstream filter and the conductor L1.

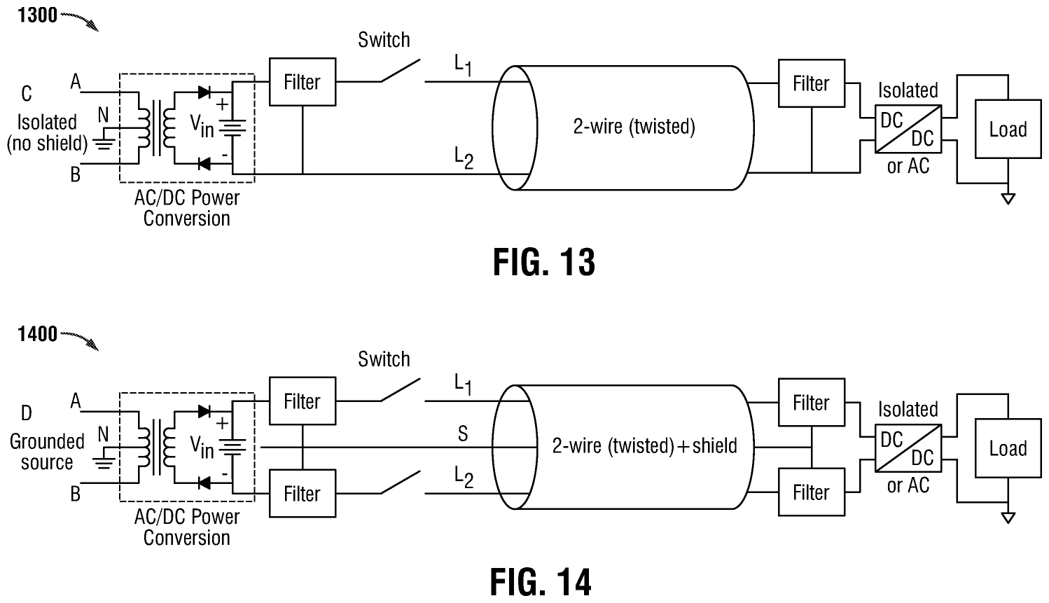

FIG. 13 illustrates a fault managed power system 1300 which employs a unipolar power configuration, in accordance with an embodiment. As shown in FIG. 13, the power system 1300 can include: a source including an upstream isolated source, an upstream power converter (e.g., AC/DC converter), an upstream filter and a single switch; a power cable; and a downstream component(s) including a downstream filter and downstream power converter (e.g., DC/DC converter or DC/AC converter) which is connected to a load. In this example, the power cable is a 2-wire (twisted) cable, which is unshielded. As shown, the power cable includes conductors, such as line L1 and L2. The upstream switch is connected between the upstream filter and the conductor L1.

FIG. 14 illustrates a fault managed power system 1400 which employs a unipolar power configuration, in accordance with an embodiment. As shown in FIG. 14, the power system 1400 can include: a source including an upstream grounded source, an upstream power converter (e.g., AC/DC converter), upstream filters and a dual switch; a power cable; and a downstream component(s) including downstream filters and downstream power converter (e.g., DC/DC converter or DC/AC converter) which is connected to a load. In this example, the power cable is a 2-wire (twisted) cable, which is shielded. As shown, the power cable includes conductors, such as line L1 and L2, and a shield s. Upstream and downstream filters are provided for conductors L1 and L2. The upstream dual switch is connected between upstream filters and their corresponding conductors (e.g., L1 and L2), and can be operated to connect or disconnect the conductors to or from a supply of electrical energy provided by the source or components thereof.

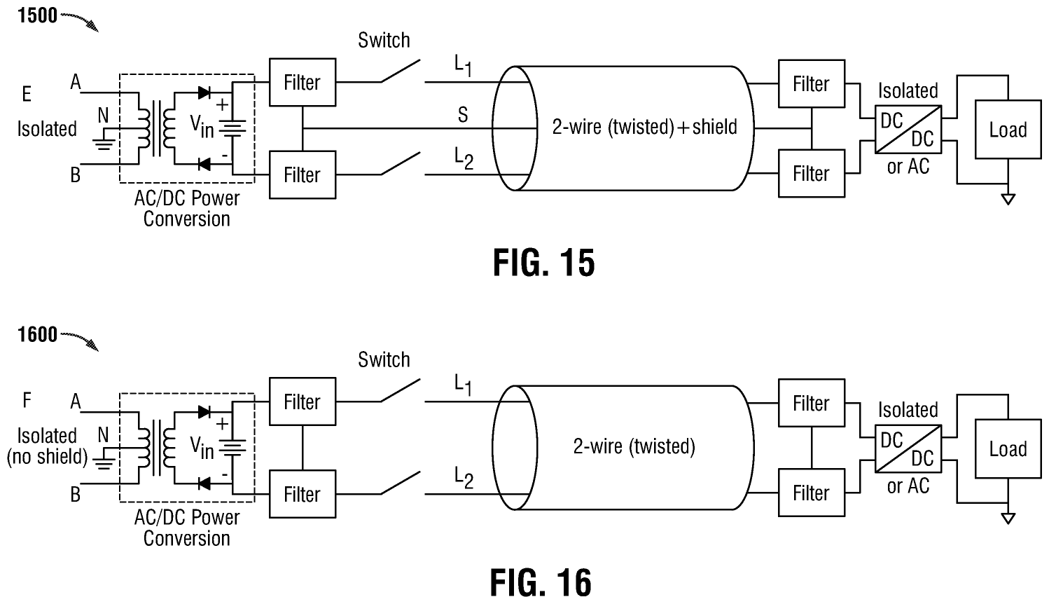

FIG. 15 illustrates a fault managed power system 1500 which employs a unipolar power configuration, in accordance with an embodiment. As shown in FIG. 15, the power system 1500 can include: a source including an upstream isolated source, an upstream power converter (e.g., AC/DC converter), upstream filters and a dual switch; a power cable; and a downstream component(s) including downstream filters and downstream power converter (e.g., DC/DC converter or DC/AC converter) which is connected to a load. In this example, the power cable is a 2-wire (twisted) cable, which is shielded. As shown, the power cable includes conductors, such as line L1 and L2, and a shield s. Upstream and downstream filters are provided for conductors L1 and L2. The upstream dual switch is connected between upstream filters and their corresponding conductors (e.g., L1 and L2), and can be operated to connect or disconnect the conductors to or from a supply of electrical energy provided by the source or components thereof.

FIG. 16 illustrates a fault managed power system 1600 which employs a unipolar power configuration, in accordance with an embodiment. As shown in FIG. 16, the power system 1600 can include: a source including an upstream isolated source, an upstream power converter (e.g., AC/DC converter), upstream filters and a dual switch; a power cable; and a downstream component(s) including downstream filters and downstream power converter (e.g., DC/DC converter or DC/AC converter) which is connected to a load. In this example, the power cable is a 2-wire (twisted) cable, which is unshielded. As shown, the power cable includes conductors, such as line L1 and L2. Upstream and downstream filters are provided for conductors L1 and L2. The upstream dual switch is connected between upstream filters and their corresponding conductors (e.g., L1 and L2), and can be operated to connect or disconnect the conductors to or from a supply of electrical energy provided by the source or components thereof.

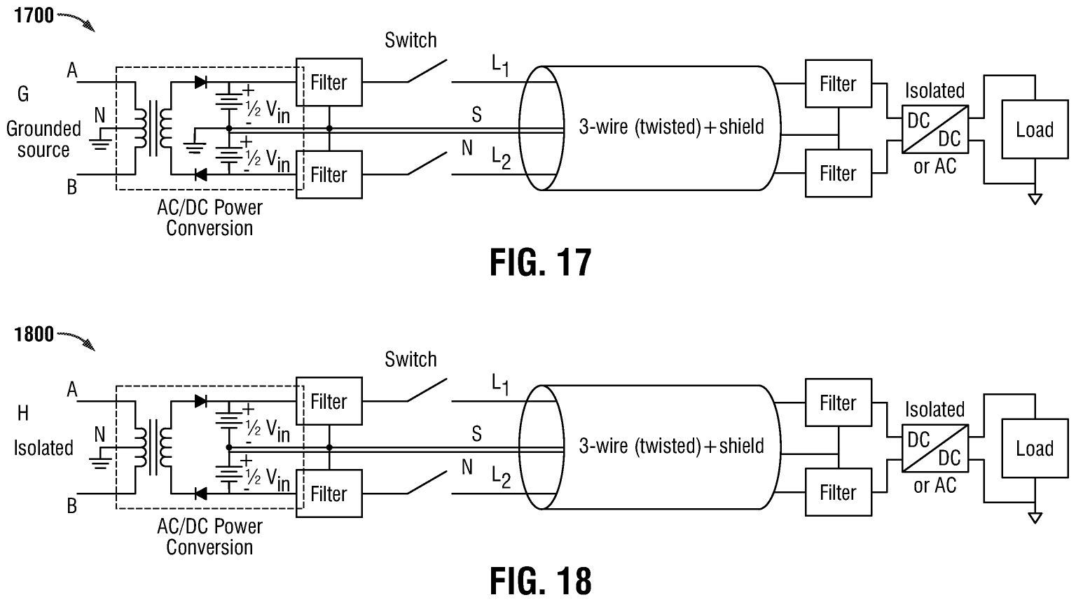

FIG. 17 illustrates a fault managed power system 1700 which employs a bipolar power configuration, in accordance with an embodiment. As shown in FIG. 17, the power system 1700 can include: a source including an upstream grounded source, an upstream power converter (e.g., AC/DC converter), upstream filters and a dual switch; a power cable; and a downstream component(s) including downstream filters and downstream power converter (e.g., DC/DC converter or DC/AC converter) which is connected to a load. In this example, the power cable is a 2-wire (twisted) cable, which is shielded, and the upstream power converter can provide for bipolar power. As shown, the power cable includes conductors, such as line L1 and L2 and Neutral N, and a shield s. Upstream and downstream filters are provided for conductors L1 and L2. The upstream dual switch is connected between upstream filters and their corresponding conductors (e.g., L1 and L2), and can be operated to connect or disconnect the conductors to or from a supply of electrical energy provided by the source or components thereof.

FIG. 18 illustrates a fault managed power system 1800 which employs a bipolar power configuration, in accordance with an embodiment. As shown in FIG. 18, the power system 1800 can include: a source including an upstream isolated source, an upstream power converter (e.g., AC/DC converter), upstream filters and a dual switch; a power cable; and a downstream component(s) including downstream filters and downstream power converter (e.g., DC/DC converter or DC/AC converter) which is connected to a load. In this example, the power cable is a 2-wire (twisted) cable, which is shielded, and the upstream power converter can provide for bipolar power. As shown, the power cable includes conductors, such as line L1 and L2 and Neutral N, and a shield s. Upstream and downstream filters are provided for conductors L1 and L2. The upstream dual switch is connected between upstream filters and their corresponding conductors (e.g., L1 and L2), and can be operated to connect or disconnect the conductors to or from a supply of electrical energy provided by the source or components thereof.

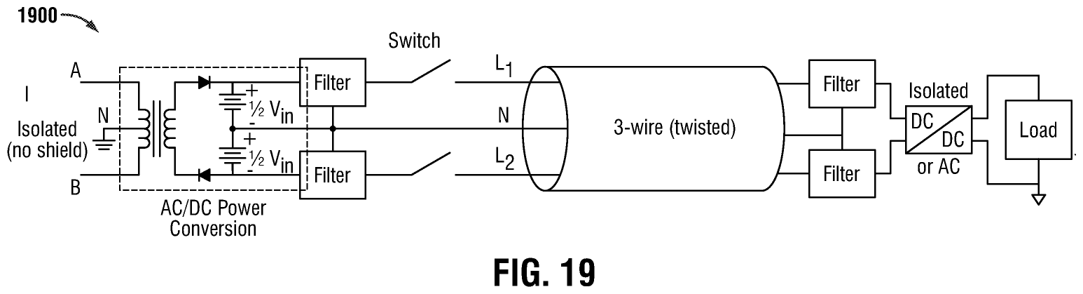

FIG. 19 illustrates a fault managed power system 1900 which employs a bipolar power configuration, in accordance with an embodiment. As shown in FIG. 19, the power system 1900 can include: a source including an upstream isolated source, an upstream power converter (e.g., AC/DC converter), upstream filters and a dual switch; a power cable; and a downstream component(s) including downstream filters and downstream power converter (e.g., DC/DC converter or DC/AC converter) which is connected to a load. In this example, the power cable is a 2-wire (twisted) cable, which is unshielded, and the upstream power converter can provide for bipolar power. As shown, the power cable includes conductors, such as line L1 and L2 and Neutral N. Upstream and downstream filters are provided for conductors L1 and L2. The upstream dual switch is connected between upstream filters and their corresponding conductors (e.g., L1 and L2), and can be operated to connect or disconnect the conductors to or from a supply of electrical energy provided by the source or components thereof.

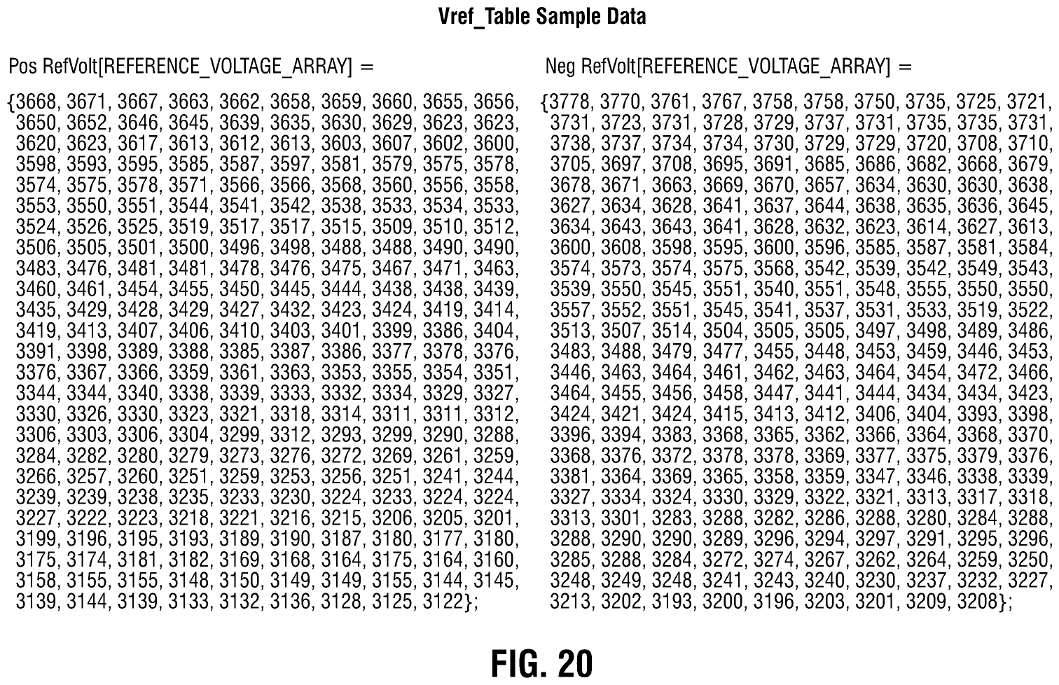

FIG. 20 illustrates an example of sample data of a calibration table such as voltage reference (Vref) Table, in accordance with an embodiment of the present disclosure. As shown, the calibration table can include a table or array of positive reference voltages and a table or array of negative reference voltages. These calibration measurements can be taken by a sensor from which sensor measurements are to be used to detect conditions on an electrical or power system. In various embodiments, the sensor can be or include an impedance sensor or RC-circuit, and the reference voltages can be measurements across a capacitor of the sensor, which can be taken when the source/source circuit is in an open circuit state (e.g., open circuit test). As described herein, the reference values can be scaled for use in performing detection of conditions, such as contact of power cable or other faults on the electrical or power system.

While particular aspects, implementations, and applications of the present disclosure have been illustrated and described, it is to be understood that the disclosure is not limited to the precise construction and compositions herein and that various modifications, changes, and variations may be apparent from the foregoing descriptions without departing from the scope of the invention as defined in the appended claims.

What is claimed is:

1. A fault managed power system, comprising:
a source switch connected to receive a source voltage from a power source, the source switch further connected to an electrical cable and controllable to connect the power source to the electrical cable;
an impedance sensor circuit connected to the electrical cable, the impedance sensor circuit configured to sense an impedance on the electrical cable; and
a controller coupled to the source switch and the impedance sensor circuit, the controller configured to receive the impedance sensed by the impedance sensor circuit and detect a presence of a fault on the electrical cable based on the impedance;
wherein the source voltage appears as current pulses on the electrical cable, each current pulse having an amplitude and a duration, and wherein the controller is configured to perform pulse duration reduction on a predefined number of current pulses to limit a cumulative effect of the predefined number of current pulses to below a predefined threshold level, without reducing the amplitude of the predefined number of current pulses.

2. The fault managed power system of claim 1, wherein the predefined threshold level is below a level that can prevent let-go or cause ventricular fibrillation in a human.

3. The fault managed power system of claim 1, wherein the controller is configured to perform the pulse duration reduction on the predefined number of current pulses by detecting whether a fault is present on the electrical cable for each current pulse, determining a maximum allowed pulse duration for each current pulse, and controlling the source switch to disconnect the power source from the electrical cable at or near expiration of the maximum allowed pulse duration, in response to detecting that a fault is present on the electrical cable.

4. The fault managed power system of claim 3, further comprising a crowbar circuit coupled to the controller and connected to the electrical cable, wherein the controller is configured to turn on the crowbar circuit at or near expiration of the maximum allowed pulse duration for each current pulse, in response to detecting that a fault is present on the electrical cable.

5. The fault managed power system of claim 3, wherein the controller is configured to determine the maximum allowed pulse duration for each current pulse by applying a current reduction multiplier to the duration of each current pulse.

6. The fault managed power system of claim 5, wherein the current reduction multiplier is one of a progressively decreasing multiplier, or a constant value.

7. The fault managed power system of claim 3, wherein the controller is configured to shut off or otherwise disable the fault managed power system after performing the pulse duration reduction a predefined number of iterations.

8. A method of managing fault in a power system, the method comprising:
connecting a power source and an electrical cable using a source switch, the source switch configured to receive a source voltage from the power source and controllable to connect the power source to the electrical cable, the source voltage appearing as current pulses on the electrical cable when the power source is connected to the electrical cable, each current pulse having an amplitude and a duration;
sensing an impedance on the electrical cable using an impedance sensor circuit connected to the electrical cable;
detecting a presence of a fault on the electrical cable based on the impedance of the electrical cable using a controller coupled to the impedance sensor circuit and the source switch; and
performing pulse duration reduction on a predefined number of current pulses using the controller to limit a cumulative effect of the predefined number of current pulses to below a predefined threshold level, without reducing the amplitude of the predefined number of current pulses.

9. The method of claim 8, wherein the predefined threshold level is below a level that can prevent let-go or cause ventricular fibrillation in a human.

10. The method of claim 8, wherein the controller performs the pulse duration reduction on the predefined number of current pulses by detecting whether a fault is present on the electrical cable for each current pulse, determining a maximum allowed pulse duration for each current pulse, and controlling the source switch to disconnect the power source from the electrical cable at or near expiration of the maximum allowed pulse duration, in response to detecting that a fault is present on the electrical cable.

11. The method of claim 10, further comprising connecting a crowbar circuit to the electrical cable and using the controller to turn on the crowbar circuit at or near expiration of the maximum allowed pulse duration for each current pulse, in response to detecting that a fault is present on the electrical cable.

12. The method of claim 10, wherein the maximum allowed pulse duration for each current pulse is determined by the controller by applying a current reduction multiplier to the duration of each current pulse.

13. The method of claim 12, wherein the current reduction multiplier is one of a progressively decreasing multiplier, or a constant value.

14. The method of claim 10, further comprising shutting off or otherwise disabling the fault managed power system using the controller after performing the pulse duration reduction a predefined number of attempts.

15. A network, comprising:
at least one network cable;
a fault managed power system connected to the at least one network cable and operable to provide a series of current pulses on the at least one network cable, each current pulse having an amplitude and a duration; and
at least one load connected to the at least one network cable and the fault managed power system, the at least one load being powered by the series of current pulses from the fault managed power system;
wherein the fault managed power system is further operable to detect a presence of a fault on the at least one network cable and perform pulse duration reduction on a predefined number of current pulses to limit a cumulative effect of the predefined number of current pulses to below a predefined threshold level, without reducing the amplitude of the predefined number of current pulses.

16. The network of claim 15, wherein the predefined threshold level is below a level that can prevent let-go or cause ventricular fibrillation in a human.

17. The network of claim 15, wherein the fault managed power system performs the pulse duration reduction on the predefined number of current pulses by detecting whether a fault is present on the network cable for each current pulse, determining a maximum allowed pulse duration for each current pulse, and switching off each current pulse at or near expiration of the maximum allowed pulse duration, in response to detecting that a fault is present on the network cable.

18. The network of claim 17, wherein the fault managed power system is further operable to crowbar each current pulse at or near expiration of the maximum allowed pulse duration for each current pulse, in response to detecting that a fault is present on the network cable.

19. The network of claim 17, wherein the maximum allowed pulse duration for each current pulse is determined by applying a current reduction multiplier to the duration of each current pulse.

20. The network of claim 19, wherein the current reduction multiplier is one of a progressively decreasing multiplier, or a constant value.
